(19) United States
(12) Patent Application Publication
(10) Pub. No.: US 2008/0081406 A1
(43) Pub. Date: Apr. 3, 2008

(54) Method of Fabricating Semiconductor Device Having Dual Stress Liner

(76) Inventors: Jae-ouk Choo, Yonging-si (KR); II-young Yoon, Hwaseong-si (KR); Seo-woo Nam, Yongin-si (KR); Ja-eung Koo, Suwon-si (KR)

Correspondence Address: F. CHAU & ASSOCIATES, LLC, 130 WOODBURY ROAD, WOODBURY, NY, 11797, US

(21) Appl. No.: 11/750,491

(22) Filed: May 18, 2007

(30) Foreign Application Priority Data
Sep. 28, 2006 (KR) 10-2006-095054

(51) Int. Cl. H01L 29/739

(52) U.S. Cl. 438/199; 257/E29.173

(57) ABSTRACT

A method of fabricating a semiconductor device comprising providing a substrate including a PMOS region and an NMOS region forming a PMOS gate electrode on the PMOS region and an NMOS gate electrode on the NMOS gate region, respectively, forming a stress liner on the PMOS region formed with the PMOS gate on the PMOS region and the NMOS region formed with the NMOS gate electrode on the NMOS region, and selectively applying radiation onto the stress liner formed on either one of the PMOS region and the NMOS region in an inert vapor ambiance.

### CROSS-REFERENCE TO RELATED PATENT APPLICATION

This application claims the benefit of Korean Patent Application No. 10206-095054: filed on Sep. 28, 2006, in the Korean Intellectual Property Office, the disclosure of which is herein incorporated by reference in its entirety.

### BACKGROUND OF THE INVENTION

1. Field of the Invention

The present invention relates to a method of fabricating a semiconductor device, and more particularly to a method of fabricating a semiconductor device having a stress liner.

2. Description of Related Art

In line with increased packing densities and demands for high performance semiconductor devices, a channel length of a transistor continues to be decrease. As the channel length is decreased, short channel effects such as hot carrier effects and punch-throughs occur. Therefore, the decrease in channel length of a transistor is considered to be limited.

Accordingly, in order to enhance the performance of a transistors methods for improving carrier mobility of a metal-oxide-metal field effect transistor (MOSFET) are contrived. As is well-known in the art, a drain current of an N-type transistor increases when tensile stress is applied to a channel of the N-type transistor, and a drain current of a P-type transistor increases when compression stress is applied to a channel of the P-type transistor.

For an example, a method of forming liners having different stresses on a substrate in which an N-type gate electrode and a P-type gate electrode are formed is disclosed in U.S. Laid-open Publication No. 2005-0093081, wherein a stress layer having a predetermined stress is formed on source/drain regions of an N-type transistor and a P-type transistor, and the stress layer formed on the source/drain regions of the N-type transistor or the P-type transistor is selectively oxidized using oxygen atoms, and thereby selectively relieving the stress from the stress layer. When the stress layer is oxidized using the oxygen atoms, a substrate under the stress layer may be oxidized due to the oxygen atoms. Particularly, when a metal silicide layer is formed on the source/drain regions, the metal silicide layer is oxidized to increase a resistance of a contact connected to the metal silicide layer.

### SUMMARY OF THE INVENTION

According to an embodiment of the present invention, a method of fabricating a semiconductor device includes providing a substrate including a PMOS region and an NMOS region, forming a PMOS gate electrode on the PMOS region and an NMOS gate electrode on the NMOS gate region, respectively, and forming a stress liner on the PMOS region with the PMOS gate electrode and on the NMOS region with the NMOS gate electrode, selectively applying radiation onto the stress liner formed on either one of the PMOS region and the NMOS region in an inert vapor ambiance.

### BRIEF DESCRIPTION OF THE DRAWINGS

The present invention will become more apparent by describing in detail exemplary embodiments thereof with reference to the attached drawings in which:

FIGS. 1A through 1E are sectional views illustrating a method of fabricating a semiconductor device according to an embodiment of the present invention;

FIG. 2 is a sectional view illustrating a method of fabricating a semiconductor device according to another embodiment of the present invention, and

FIG. 3 is a sectional view illustrating a method of fabricating a semiconductor device according to another embodiment of the present invention.

### DETAILED DESCRIPTION OF EXAMPLARY EMBODIMENTS

The present invention will now be described more fully with reference to the accompanying drawings, in which exemplary embodiments of the invention are shown. The invention may, however, be embodied in many different forms and should not be construed as being limited to embodiments set forth herein; rather, embodiments are provided so that this disclosure will be thorough and complete, and will fully convey the concept of the invention to those skilled in the art. Like reference numerals in the drawings denote like elements, and thus their description may be omitted.

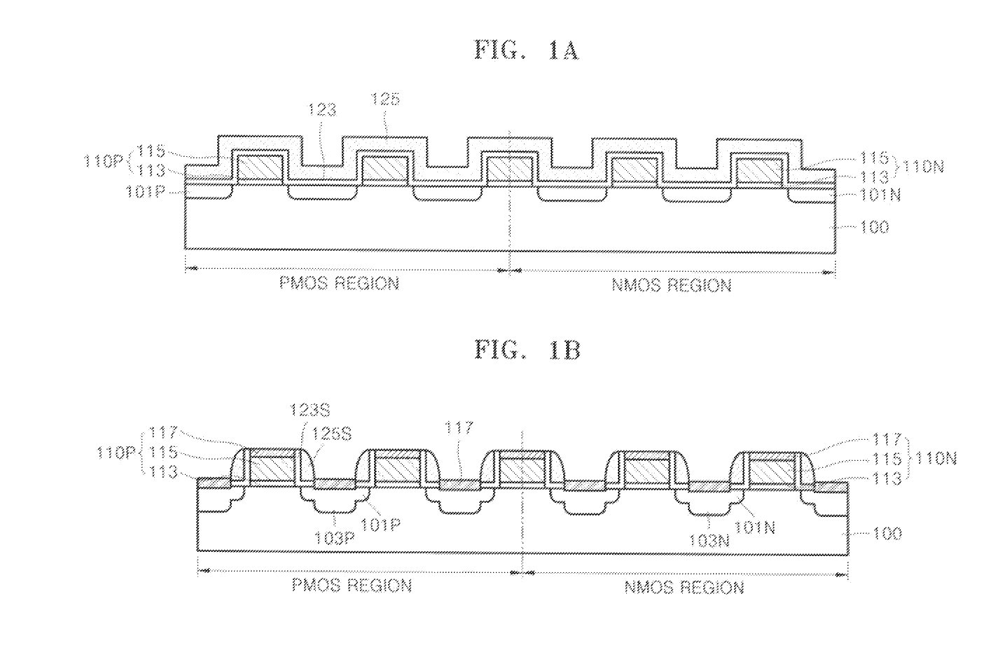

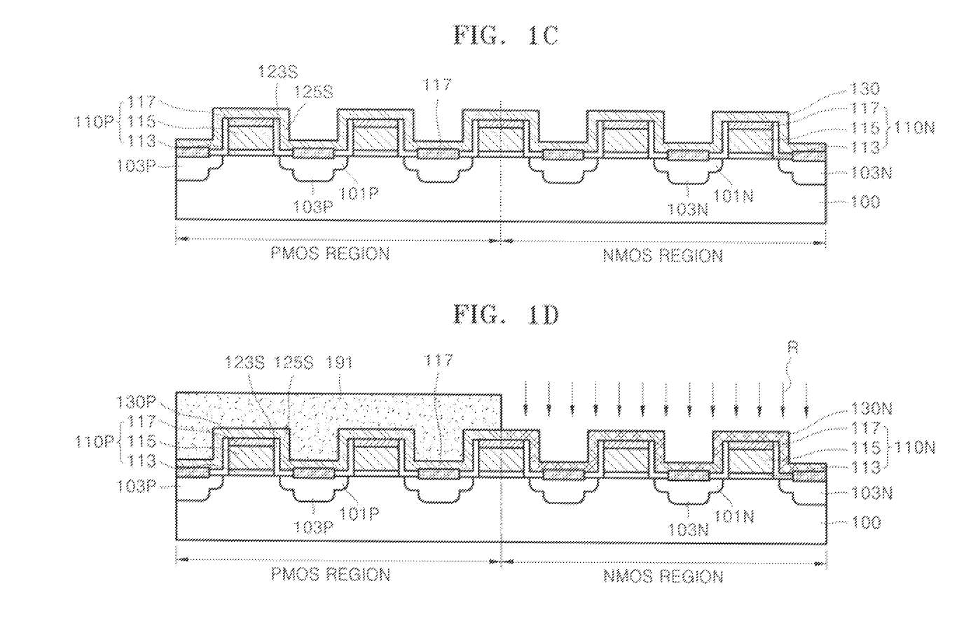

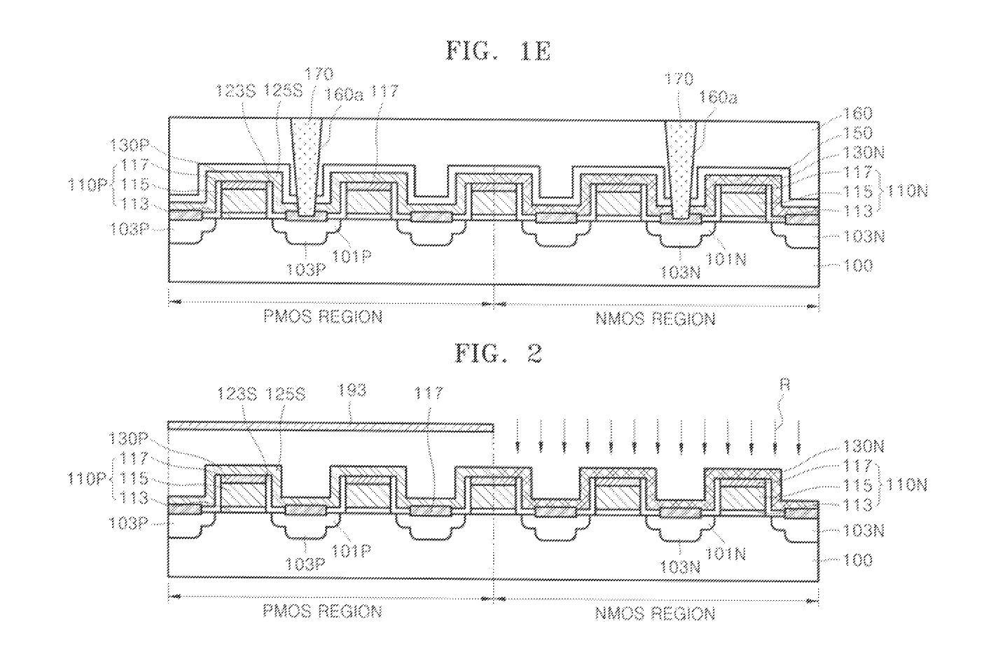

FIGS. 1A through 1E are sectional views illustrating a method of fabricating a semiconductor device according to an embodiment of the present invention.

Referring to FIG. 1A, a substrate 100 includes a PMOS region and an NMOS region. The substrate 100 is a semiconductor substrate and may be a silicon substrate. A device isolation structure (not shown) is formed in the substrate 100 to define an active region.

A gate insulating layer 113 and a gate conductive layer 115 are sequentially stacked on the substrate 100, are sequentially etched to form NMOS and PMOS gate electrodes 110N and 110P respectively formed on the NMOS and PMOS regions of the substrate 100. The gate conductive layer 115 may be a polysilicon layer.

An offset spacer layer 123 is stacked on the NMOS and PMOS gate electrodes 110N and 110P. The offset spacer layer 123 may conformally cover the NMOS and PMOS gate electrodes 110N and 110P, which may be a silicon oxide layer.

A first photoresist pattern (not shown) selectively exposing the NMOS region is formed on the substrate 100 with the offset spacer layer 123. Using the first photoresist pattern as a mask, an N-type impurity having a low density is implanted into the NMOS region of the substrate 100. The first photoresist layer, which functions as a mask, is removed. As such, an N-type lightly doped drain (LDD) region 101N is formed in the substrate 100 adjacent to the NMOS gate electrode 110N, i.e., within the NMOS region, and thereby defining an NMOS channel region under the NMOS gate electrode 101N. Similarly, a second photoresist pattern (not shown) selectively exposing the PMOS region is formed on the substrate 100 with the offset spacer layer 123. Using the second photoresist pattern as a mask, a P-type impurity at a low density is implanted into the PMOS region of the substrate 100. The second photoresist layer, which functions as a mask, is removed. As such, a P-type LDD region 101P is formed in the substrate 100 adjacent to the PMOS gate electrode 110P, i.e., within the PMOS region, thereby defining a PMOS channel region under the PMOS gate electrode 110P.

A sidewall spacer layer 125 is stacked on the offset spacer layer 123. The sidewall spacer layer 125 may be composed of SiNx or SiON.

Referring to FIG. 11B the sidewall spacer layer 125 is anisotropically etched to form sidewall spacers 125S on sidewalls of the NMOS and PMOS gate electrodes 110N and 110P. The offset spacer layer 123 is exposed around the sidewall spacers 125S. Using the sidewall spacers 125S as a mask, the offset spacer layer 123 is anisotropically etched. Consequently, an L-shaped offset spacer 123S is formed between the gate electrodes 110N and the sidewall spacers 125S, and the substrate 100 and the sidewall spacers 125S.

A third photoresist pattern (not shown) selectively exposing the NMOS region is formed. Using the third photoresist pattern, the NMOS gate electrode 110N and the sidewall spacers 125S as masks, an N-type impurity is implanted at a high density into the NMOS region. The photoresist pattern, which is formed as a mask, is removed. By doing so, N-type source/drain regions 103N are formed in the NMOS region adjacent to the sidewall spacers 125S. Similarly, a fourth photoresist pattern (not shown) selectively exposing the PMOS region is formed. Using the fourth photoresist pattern, the PMOS gate electrode 110P and the sidewall spacers 125S as masks, a P-type impurity is implanted at a high density into the PMOS region. The fourth photoresist pattern, which is formed as a mask, is removed. By doing so, P-type source/drain regions 103P are formed in the PMOS region adjacent to the sidewall spacers 125S.

A metal layer (not shown) is stacked on the NMOS and PMOS gate electrodes 110N and 110P and the N-type and P-type source/drain regions 103N and 103P, which are annealed at a predetermined temperature. Thus, the metal layer reacts with the upper surfaces of the NMOS and PMOS gate electrodes 110N and 110P and the upper surfaces of the NMOS and PMOS source/drain regions 103N and 103P, and thereby forming a metal silicide layer 117. The metal layer may be a tungsten layer, a cobalt layer or a nickel layer. Accordingly, the metal silicide layer 117 may be a tungsten silicide layer, a cobalt silicide layer or a nickel silicide layer.

Referring to FIG. 1C, the sidewall spacers 125S are removed exposing the L-shaped offset spacers 123S formed on the sidewalls of the NMOS and PMOS gate electrodes 110N and 110P.

A stress liner 130 is formed on the NMOS and PMOS gate electrodes 110N and 110P, the L-shaped offset spacers 123S exposed on the sidewalls of the NMOS and PMOS gate electrodes 110N and 110P, and the NMOS and PMOS source/drain regions 103N and 103P. The stress liner 130 may conformally cover the NMOS and PMOS gate electrodes 110N and 110P. The stress liner 130 may be composed of SiCN, SiN, SiON, SiBN, SiO₂, SiC, SiCH, SiCOH or a composite layer of these materials. The stress liner 130 may be a SiCN layer having a stress variation due to a stress reversing treatment as will be described later. The stress liner 130 has a thickness of about 1 Å˜2000 Å. Preferably, the thickness of the stress liner 130 may be about 500 Å˜1000 Å so as to apply sufficient stress to the NMOS channel region and PMOS channel region.

Referring to FIG. 1D, a fifth photoresist pattern 191 exposing the NMOS region is formed on the stress liner 130. In other words, the photoresist pattern 191 is formed on the PMOS region to expose the NMOS region. The photoresist pattern 191 may be formed to a thickness of about 50 Å˜5000 Å so as to sufficiently shield the PMOS region from radiation R as will be described later.

Using the photoresist pattern 191 as a mask, radiation R such as ultraviolet rays or electron beams are applied onto the stress liner 130 formed on the exposed NMOS region in an inert vapor ambiance. Therefore, the molecular structure of the stress liner 130 on the NMOS region is changed by the radiation R so that the polarity of the stress is reversed. More specifically, a compression stress of as-deposited stress liner 130 is reversed into a tensile stress by the radiation R. In case that a SiCN layer is used as the stress liner and ultraviolet rays are radiated onto the SiCN layer, a compression stress of the stress liner 130 of about −500 MPa prior to the radiating of the ultraviolet rays is reversed to a tensile stress of about 500 MPa.

As a result, a tensile stress liner 130N covering the NMOS gate electrode 110N with tensile stress is disposed on the NMOS region. Also, a compression stress liner 130P covering the PMOS gate electrode 110P with compression stress is disposed on the PMOS region. The tensile stress liner 130N applies tensile stress to the NMOS channel region in order to enhance electron mobility in the NMOS channel region. The compression stress liner 130P applies compression stress to the PMOS channel region in order to enhance hole mobility in the PMOS channel region. Therefore, the performance of NMOS and PMOS transistors can be improved by the tensile and compression stress liners 130N and 130P respectively.

Moreover, a method of applying radiation R onto the stress liner 130 in the inert vapor ambiance can minimize damage to the NMOS and PMOS source/drain regions 103N and 103P or to the metal silicide layer 117 under the stress liner 130, which is different from a method of oxidizing the stress liner to reverse the polarity of the stress. The inert vapor may be of He, Ar Xe, Kr or a combination of these.

More specifically, a wavelength of the ultraviolet rays radiated on the stress liner 130 may be about 10 nm˜500 nm. The temperature of the substrate 100 may be about 25° C.˜500° C. Also, the radiation time of the ultraviolet rays may be about 0.5˜60 minutes. The energy of the electron beams radiated on the stress liner 130 may be about 0.5 Kev˜100 KeV, and the current density of the electron beams may be about 0.1˜100 uA/cm². The time of radiating the electron beams may be about 0.5˜60 minutes.

Referring to FIG. 1E, the photoresist pattern 191 of FIG. 1D is removed to expose the compression stress liner 130P on the PMOS region.

Thereafter, a buffer insulating layer 150 is stacked on the tensile and compression stress liners 130N and 130P. The buffer insulating layer 150 may be formed by thermal chemical vapor deposition (CVD), plasma enhanced CVD (PECVD), unbiased high density plasma (HDP-CVD) or atomic layer deposition (ALD). Particularly, in the case of HDP-CVD where no bias is applied, the substrate 100 is not voltage biased. Accordingly, the high density plasma that is liable for damaging the tensile and compression stress liners 130N and 130P may not be generated around the substrate 100. Additionally, in the case of PECVD, the high density plasma that is liable for damaging the tensile and compression stress liners 130N and 130P may not be generated. Therefore, when forming the buffer insulating layer 150, plasma damage cannot be caused to the tensile and compression stress liners 130N and 130P. Furthermore, the buffer insulating layer 150 may be formed by tetra-ethyl-ortho-silicate (TEOS) or O₃-TEOS to a thickness of about 50 Å˜200 Å.

The interlayer insulating layer 160 is formed on the buffer insulating layer 150, and then the interlayer insulating layer 160 is planarized. The interlayer insulating layer 160 may be a silicon oxide layer. The interlayer insulating layer 160 may be formed using HDP-CVD method. The interlayer insulating layer 160 formed by HDP-CVD method, i.e., high density plasma interlayer insulating layer 160 has an excellent gap-fill capability as compared with an insulating layer formed by other methods. Accordingly, the high density plasma interlayer insulating layer 160 can completely be filled into a gap between the NMOS and PMOS gate electrodes 110N and 110P.

However, if the tensile and compression stress liners 130N and 130P contact the high density plasma produced when forming the high density plasma interlayer insulating layer 160, the high density plasma damages the tensile and compression stress liners 130N and 130P to relieve the stress from the tensile and compression stress liners 130N and 130P. The buffer insulating layer 150 is employed to prevent the high density plasma damage on the tensile and compression stress liners 130N and 130P. Therefore, the amount of stress of the tensile and compression stress liners 130N and 130P can be maintained.

A sixth photoresist pattern (not shown) is formed on the interlayer insulating layer 160, and contact holes 160a are formed by etching the interlayer insulating layer 160 and the buffer insulating layer 150 using the photoresist pattern as a mask. By doing so, the tensile and compression stress liners 130N and 130P are exposed in the contact holes 160a. When the tensile and compression stress liners 130N and 130P are nitride layers, the tensile and compression stress liners 130N and 130P act as etch stop layers when forming the contact holes 160a. The tensile and compression stress liners 130N and 130P that are exposed in the contact holes 160a are etched to expose respective NMOS source/drain regions 103N and the PMOS source/drain regions 103P. A conductive layer is stacked on the substrate 100 in which the contact holes 160a are formed, and is subjected to chemical mechanical polishing (CMP) until the interlayer insulating layer 160 is exposed. Thus, source/drain electrodes 170 are formed connected to the NMOS and PMOS source/drain regions 103N and 103P.

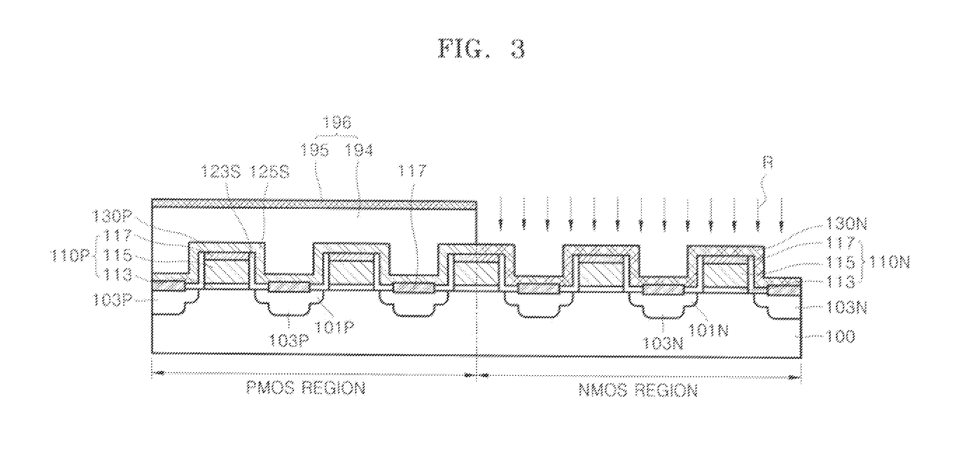

FIG. 2 is a sectional view illustrating a method of fabricating a semiconductor device according to another embodiment of the present invention.

Referring to FIG. 2, a resultant structure fabricated by the method described with reference to FIGS. 1A through 1C is provided. A photomask 193 exposing an NMOS region is disposed over the resultant structure, i.e., a substrate 100 on which a stress liner is formed. In other words, the photomask 193 shields the PMOS region and exposes the NMOS region. Using the photomask 193 as a mask, radiation R such as ultraviolet rays or electron beams applied onto the stress liner formed on the exposed NMOS region in an inert vapor ambiance. Therefore, the polarity of the stress liner on the NMOS region is inverted by the radiation R, so that the stress liner has tensile stress. Consequently, a tensile stress liner 130N covering an NMOS gate electrode 110N and having tensile stress is located on the NMOS region, and a compression stress liner 130P covering a PMOS gate electrode 110P and having compression stress is disposed on the PMOS region.

In this case, the photomask 193 does not cover an entire region of the substrate 100, but covers a partial region, so-called a unit shot region. Accordingly, the emission of the radiation R using the photomask 193 may be performed per unit shot region.

Thereafter, the fabrication of the semiconductor device can be continued using the method described with reference to FIG. 1E.

FIG. 3 is a sectional view illustrating a method of fabricating a semiconductor device according to another embodiment of the present invention.

Referring to FIG. 3, a resultant structure fabricated by the method described with reference to FIGS. 1A through 1C is provided. A hard mask pattern 196 exposing an NMOS region is disposed on the resultant structure, i.e. a substrate 100 on which a stress liner is formed. The hard mask pattern 196 may be an insulating layer, a metal layer or a dual layer of these layers, and has a thickness of about 10 Å˜100 Å. More specifically, the hard mask pattern 196 may have an oxide layer 194 and a mask layer 195 stacked on the oxide layer 194. The oxide layer 194 may be formed using thermal CVD, PECVD, unbiased HDP-CVD or ALD. The mask layer 195 may be composed of SiCN, SiN, SiON, SiBN, SiC, SiCH, SiCOH or a metal. Preferably, the mask layer 195 may be a metal layer.

In this case, the hard mask pattern 196 is formed on a PMOS region to shield the PMOS region and expose the NMOS region. Using the hardmask pattern 196 as a mask, radiation R such as ultraviolet rays or electron beams is applied onto the stress liner formed on the exposed NMOS region in an inert vapor ambiance. Therefore, the polarity of the stress liner on the NMOS region is reversed by the radiation R, so that the stress liner has a tensile stress. Consequently, a tensile stress liner 130N covering the NMOS gate electrode 110N and having tensile stress is located on the NMOS region, and a compression stress liner 140P covering a PMOS gate electrode 110P and having a compression stress is disposed on the PMOS region.

Thereafter, the mask layer 195 is selectively removed, or the entire hard mask pattern 196 is removed. The fabrication of the semiconductor device can be continued using the method described with reference to FIG. 1E.

Above-described embodiments suggest the method of forming the compression stress liners on the NMOS region and the PMOS region, and selectively reversing the compression stress from the compression stress liner on the NMOS region into tensile stress. However, the present invention is not restricted to the foregoing method, and may also be applied to a method of forming tensile stress liners on an NMOS region and a PMOS region and selectively changing tensile stress of the tensile stress liner on the PMOS region to compression stress.

As a result, according to an embodiment of the present invention described as above, stress liners are formed on a substrate having an NMOS region and a PMOS region. By selectively applying radiation onto the stress liner on either the NMOS region and the PMOS region, a tensile stress liner and a compression stress liner are formed on the NMOS region and the PMOS region, respectively. Therefore, respective performances of an NMOS transistor and a PMOS transistor can be enhanced.

Furthermore, the radiation is applied onto the stress liner in an inert vapor ambiance, so that damage on a substrate or a layer under the stress liner, more specifically, a metal silicide layer, can be reduced.

Additionally, a buffer insulating layer is employed on the stress liner to prevent damage on the stress liner caused by high density plasma produced during the forming of an interlayer insulating layer. Therefore, the stress of the stress liner can be maintained constant even after the forming of the interlayer insulating layer.

While the present invention has been particularly shown and described with reference to exemplary embodiments thereof, it will be understood by those of ordinary skill in the art that various changes in form and details may be made therein without departing from the spirit and scope of the present invention.

What is claimed is:

1. A method of fabricating a semiconductor device comprising:
providing a substrate including a PMOS region and an NMOS region;
forming a PMOS gate electrode on the PMOS region and an NMOS gate electrode on the NMOS gate region, respectively; and
forming a stress liner on the PMOS region with the PMOS gate electrode and on the NMOS region with the NMOS gate electrode,
selectively applying radiation onto the stress liner formed on either one of the PMOS region and the NMOS region in an inert vapor ambiance.

2. The method of claim 1, wherein the stress liner is a compression stress liner having compression stress; and
the radiation is selectively applied onto the stress liner formed on the NMOS region.

3. The method of claim 1, wherein the radiation comprises one of ultraviolet rays and electron beams.

4. The method of cairn 1, wherein the stress liner is a layer composed of a material selected from a group consisting of SiCN, SiON, SiBN, SiO₂, Sic. SiCH and SiCOH.

5. The method of cairn 4, wherein the stress liner is a SiCN layer.

6. The method of cairn 4, wherein the stress liner has a thickness of about 50 Å˜1000 Å.

7. The method of claim 1, before the forming of the stress liner, further comprises:
forming P-type source/drain regions in the substrate adjacent to the PMOS gate electrode;
forming N-type source/drain regions in the substrate adjacent to the NMOS gate electrode, and
forming a metal silicide layer on upper surfaces of the PMOS and NMOS gate electrodes and the P-type and N-type source/drain regions.

8. The method of claim 1, wherein the radiation is selectively applied onto the stress liner formed on one of the PMOS region and the NMOS region using a mask, wherein the mask is one of a photoresist pattern, a hard mask pattern and a photomask.

9. The method of claim 1 further comprising.
forming a buffer insulating layer on the stress liner after the radiation is selectively applied; and
forming a high density plasma interlayer insulating layer on the buffer insulating layer.

10. The method of claim 9, wherein the buffer insulating layer is formed using one of thermal chemical vapor deposition (CVD) plasma enhanced CVD (PECVD), unbiased high-density plasma (HDP)-CVD and atomic layer deposition (ALD).

11. The method of claim 9, wherein the buffer insulating layer is formed using one of tetra-ethyl-ortho-silicate (TEOS) and O₃-TEOS.
